(19) United States
(12) Patent Application Publication
(10) Pub. No.: US 2023/0006108 A1
(43) Pub. Date: Jan. 5, 2023

(54) HOUSING FOR AN OPTOELECTRONIC SEMICONDUCTOR COMPONENT, AND OPTOELECTRONIC SEMICONDUCTOR COMPONENT

(71) Applicant: ams-OSRAM International GmbH, Regensburg (DE)

(72) Inventor: Karlheinz ARNDT, Bad Abbach (DE)

(21) Appl. No.: 17/802,327

(22) PCT Filed: Mar. 5, 2021
(86) PCT No.: PCT/EP2021/055581

§ 371 Date: Aug. 25, 2022

(30) Foreign Application Priority Data
Mar. 18, 2020 (DE) 10 2020 107 409.3

(51) Int. Cl. H01L 33/48; H01L 33/62

(52) U.S. Cl. CPC H01L 33/486; H01L 33/62

(57) ABSTRACT

Described is a housing for an optoelectronic semiconductor component with a mounting side a lead frame, and a housing body which is integrally moulded onto the lead frame, wherein the lead frame has a first lead frame part and a second lead frame par, wherein the housing body comprises a cavity on a front side facing away from the mounting side for accommodating a semiconductor chip, and wherein the lead frame is exposed solely at a first connection point of the first lead frame part and at a second connection point of the second lead frame part of the lead frame in the cavity. Additionally, an optoelectronic semiconductor component is also described.

The present application relates to a housing for an optoelectronic semiconductor component, and to an optoelectronic semiconductor component.

For optoelectronic semiconductor components, for example light-emitting diodes, or LEDs for short, the semiconductor chips can be mounted in housings with a lead frame. To reduce reflection losses, the lead frame can be coated with silver. There is the risk, however, that this silver will discolour on account of corrosion during operation of the component, thus resulting in increased reflection losses.

One object is to provide an optoelectronic semiconductor component that has good properties in a simplified manner and reliably.

This object is achieved, inter alia, by a housing according to claim 1. Further embodiments and expedient features are the subject of the dependent claims.

A housing for an optoelectronic semiconductor component is described, in particular as a surface-mountable component (surface-mounted device, or SMD). The housing has, for example, a mounting side, on which all electrical contacts necessary for electrically contacting the optoelectronic semiconductor component are accessible externally. In the vertical direction, that is to say perpendicularly to the mounting side, the housing extends for example between the mounting side and a front side facing away from the mounting side. For example, the housing extends along a longitudinal axis of the housing between two first side faces. The housing extends for example between two second side faces of the housing perpendicularly to the longitudinal axis. The longitudinal axis and the transverse axis, in plan view of the housing, run in particular centrally in each case, so that an intersection point between the longitudinal axis and the transverse axis forms for example a centre point of the housing in plan view of the housing.

According to at least one embodiment of the housing, the housing has a lead frame and a housing body, which is integrally moulded onto the lead frame. The housing body comprises a plastics material for example. The housing body is produced for example by a moulding method.

A moulding method is understood generally to be a method by means of which a moulding compound can be formed in accordance with a predefined shape and, as necessary, hardened. In particular, the term “casting method” includes moulding, film assisted moulding, injection moulding, transfer moulding, and compression moulding.

The lead frame extends in a vertical direction, for example between a rear side of the lead frame and a front side of the lead frame. For example, the lead frame is a partially etched lead frame, also referred to as a semi-etched lead frame). This means that the lead frame has regions of different thickness, wherein the thickness of the lead frame relates to the vertical extent. For this purpose, a starting sheet of the lead frame, for example a coated or uncoated copper sheet, can be partially etched from the front side and/or from the rear side.

According to at least one embodiment of the lead frame, the lead frame comprises a first lead frame part and a second lead frame part. The first lead frame part and the second lead frame part are arranged without overlapping each other, in particular in plan view of the housing, and are not directly connected to each other in an electrically conductive manner at any point. In particular, the first lead frame part and the second lead frame part are connected to each other in a mechanically stable manner only via the housing body.

The first lead frame part and the second lead frame part can each be formed in one piece in the sense of a coherent body.

According to at least one embodiment of the housing, the housing body comprises a cavity on the front side of the housing for accommodating a semiconductor chip. A vertical extent of the cavity, i.e. a distance between a bottom face of the cavity and the front side of the housing, is in particular so large that the semiconductor chip to be accommodated is arranged completely within the cavity.

According to at least one embodiment of the housing, the lead frame is exposed in the cavity only at a first connection point of the first lead frame part and at a second connection point of the second lead frame part of the lead frame. In other words, in a plan view of the housing, only the first connection point and the second connection point of the lead frame are visible. In particular, the first connection point and the second connection point are completely covered by the semiconductor chip when a semiconductor chip to be accommodated in the cavity is mounted as intended.

The first connection point and the second connection point are set up in particular for the electrical contacting of a semiconductor chip with two electrical contacts on the side of the semiconductor chip facing the mounting side, for example for the mounting of semiconductor chips in flip-chip geometry.

For example, the first connection point and the second connection point are each at most half the size of the semiconductor chip to be accommodated.

In at least one embodiment of the housing for an optoelectronic semiconductor component, the housing has a mounting side, a lead frame, and a housing body which is integrally moulded onto the lead frame, wherein the lead frame has a first lead frame part and a second lead frame part, and the housing body having a cavity, for accommodating an optoelectronic semiconductor chip, on a front side facing away from the mounting side. The lead frame is exposed in the cavity only at a first connection point of the first lead frame part and at a second connection point of the second lead frame part of the lead frame.

When mounting an optoelectronic semiconductor chip in such a housing, there are no exposed regions of the lead frame inside the cavity after the mounting the optoelectronic semiconductor chip, for example by means of a connecting means, such as a solder. In particular, the parts of the lead frame not covered by the housing body can be completely covered by the connecting means.

The danger that parts of the lead frame exposed in the cavity will corrode is thus avoided. By contrast, in conventional optoelectronic semiconductor components, parts of the lead frame to the side of the semiconductor chip are not covered by the housing body. If these parts are only covered by polymer materials, such as a potting compound of the semiconductor chip, penetration paths can lead to corrosion. By contrast, in the case of the described housing, the potting compound itself does not have to be able to block penetration paths and thus suppress the penetration of corrosion-causing gases, such as hydrogen sulfide. Materials such as silicones, which have a comparatively high permeability to hydrogen sulfide, can therefore also be used for the potting compound.

According to at least one embodiment of the housing, a bottom face of the cavity in the region of the first connection point and the second connection point has an indentation in which the first connection point and the second connection point are exposed. The indentation can be a common indentation for both connection points. In this case, the indentation extends continuously over the first connection point and the second connection point. Deviating from this, the first connection point and the second connection point can each be assigned a separate indentation. The indentation is designed, for example, to accommodate a connecting means, such as a solder.

A vertical extent of the indentation, i.e. a vertical distance of the housing body in the region of the indentation from the bottom face of the housing body, is preferably small compared to the vertical extent of the cavity. For example, the vertical extent of the indentation is at least twice or at least five times as large as the vertical extent of the cavity.

According to at least one embodiment of the housing, the first lead frame part has a first inner region. The first inner region overlaps with the first connection point, in particular in plan view of the housing. The first inner region is exposed on the mounting side of the housing. In particular, the first inner region forms the rear side of the lead frame at points.

According to at least one embodiment of the housing, the first lead frame part has a first edge region, wherein the first edge region is exposed on the mounting side of the housing and/or the first edge region being exposed at a side face of the housing. The side face of the housing is in particular a first side face which delimits the housing along the longitudinal axis in the lateral direction.

The first inner region and the first edge region are in particular parts of a coherent first lead frame part.

According to at least one embodiment of the housing, the first inner region and the first edge region are connected to each other via a first front-side region of the first lead frame part. The first front side region is distanced from the mounting side. Thus, the front-side region forms the front side of the lead frame at points, but does not extend to the rear side of the lead frame in the vertical direction. In particular, the front-side region is covered by the housing body in a rear view of the housing and is thus not visible. Preferably, the first inner region and the first edge region are only connected to each other via the first front-side region.

According to at least one embodiment of the housing, the first edge region has a recess that is accessible on the mounting side and on the side face of the housing. For example, the recess extends only partially through the lead frame in the vertical direction. However, the recess can also extend completely through the lead frame in the vertical direction. The recess can fulfil the function of a solder control structure, so that it can be seen from the side of the housing whether soldering of the housing, for example to a connection carrier such as a printed circuit board, has been reliably carried out.

According to at least one embodiment of the housing, the first front-side region runs along two edges of the first inner region in plan view of the housing. The two edges run in particular obliquely or perpendicularly to each other. This increases the mechanical stability of the housing.

Furthermore, the reliability in the production of the housing is increased, since the first inner region for the formation of the housing body can be reliably pressed into the film used for this purpose by means of a film assisted moulding method. Unintentional covering of the rear side of the lead frame with material for the housing body can thus be efficiently avoided.

According to at least one embodiment of the housing, the first lead frame part is interrupted between the first inner region and the first edge region in plan view of the housing along the longitudinal axis of the housing. Thereby, a direct force transfer along the longitudinal axis between the first edge region and the first inner region can be avoided or at least reduced. Such a force transfer can occur, for example, when the housing is heated during soldering to a connection carrier and different thermal expansion coefficients of the materials used lead to thermomechanical stresses. With such a housing, the risk of damage to a semiconductor component during mounting of the housing can thus be reduced.

According to at least one embodiment of the housing, the first inner region and the first edge region are connected to each other only on one side of the longitudinal axis of the housing via the first front-side region, as seen in plan view of the housing along said longitudinal axis. In particular, the first lead frame part does not form a closed structure such as an O-shaped structure when viewed in plan view of the housing. For example, the part of the first front-side region that connects the first inner region to the first edge region is C-shaped in plan view.

According to at least one embodiment of the housing, the first front-side region of the first lead frame part comprises a first extension extending between the second connection point and a second side face of the housing running parallel to the longitudinal axis. For example, the first extension protrudes beyond the transverse axis of the housing. In other words, the first extension is located, at least at points, on that side of the transverse axis of the housing on which the second connection point of the second lead frame part is arranged, in plan view of the housing. Thus, in a side view of the housing, the first extension of the first lead frame part overlaps with the second lead frame part. It has been shown that such an extension can improve the mechanical stability of the housing, in particular with respect to bending.

According to at least one embodiment of the housing, the first extension runs along at least 50% of the extent of the second connection point, as seen along the longitudinal axis of the housing. The first extension can also extend over the entire length of the second connection point, as seen along the longitudinal axis. The mechanical stability of the housing is thus further improved.

According to at least one embodiment of the housing, an area dimension of the first connection point and an area dimension of the second connection point is in each case at most 30% of an area dimension of the bottom face of the cavity. The first connection point and the second connection point are thus small compared to the total area of the bottom face of the cavity.

When an optoelectronic semiconductor chip is mounted in the cavity as intended, it is thus easily ensured that the first connection point and the second connection point are completely covered by the optoelectronic semiconductor chip.

The first lead frame part and the second lead frame part can be similar in respect of their basic shape. In particular, the second lead frame part can have a second inner region and/or a second edge region and/or a second front-side region and/or a second extent, and these elements can have some or also all of the features listed in conjunction with the first lead frame part.

According to at least one embodiment of the housing, the second lead frame part and the first lead frame part are point-symmetrical to one another in respect of their basic shape, in particular point-symmetrical to the centre point of the housing. For example, the second lead frame part and the first lead frame part differ only by a marking for simplified identification of the polarity of the contacts of the housing. In particular, the first lead frame part and the second lead frame part are not axis-symmetrical in respect of their basic shape, neither to the longitudinal axis nor to the transverse axis.

Furthermore, an optoelectronic semiconductor component with a housing is specified. The housing described above is particularly suitable as a housing. Features mentioned in conjunction with the housing can therefore also be used for the optoelectronic semiconductor component, and vice versa.

The optoelectronic semiconductor component comprises, in particular, an optoelectronic semiconductor chip which is arranged, for example, in the cavity of the housing and is electrically conductively connected to the first connection point and the second connection point. The semiconductor chip is formed, for example, to generate and/or receive radiation, for example in the visible, ultraviolet or infrared spectral range. In particular, the optoelectronic semiconductor chip is formed with two contacts on the side facing the mounting side, for example as a flip chip.

According to at least one embodiment of the optoelectronic semiconductor component, the optoelectronic semiconductor chip completely covers the first connection point and the second connection point. Thus, in plan view of the optoelectronic semiconductor component, the lead frame of the optoelectronic semiconductor component is not visible within the cavity. All parts of the lead frame that are exposed in the cavity of the housing are therefore covered by the semiconductor chip when the semiconductor chip is in the mounted state.

According to at least one embodiment of the optoelectronic semiconductor component, the first connection point and the second connection point are each at most half the size of the optoelectronic semiconductor chip in plan view of the semiconductor component. In particular, the optoelectronic semiconductor chip overlaps both the first connection point and the second connection point.

According to at least one embodiment of the optoelectronic semiconductor component, the optoelectronic semiconductor chip is embedded in a potting compound. The potting compound is in particular permeable to the radiation to be received and/or generated in the optoelectronic semiconductor chip. Preferably, the potting compound does not at any point directly border the lead frame. For the potting compound, the choice of material can therefore be selected independently of its adhesion properties to metal surfaces.

Further embodiments and practicalities will result from the following description of the exemplary embodiments in conjunction with the figures.

In the figures:

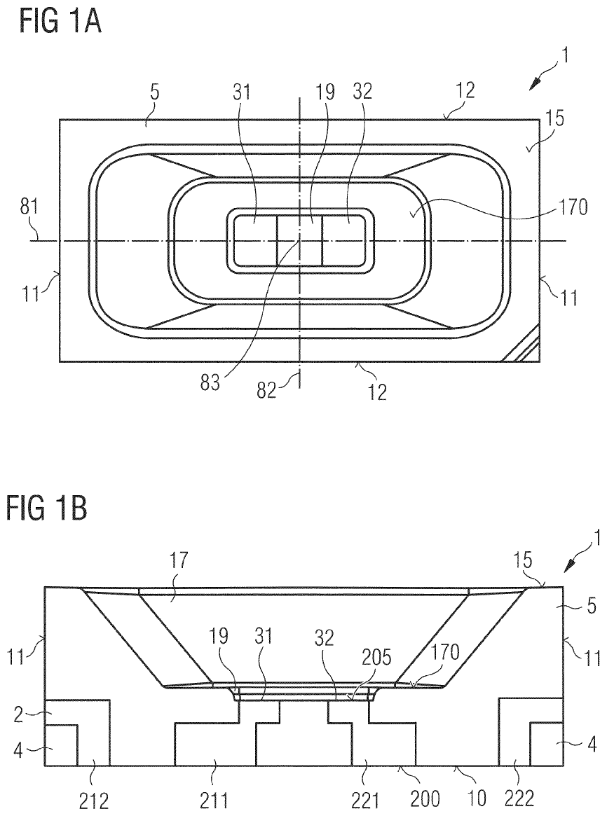

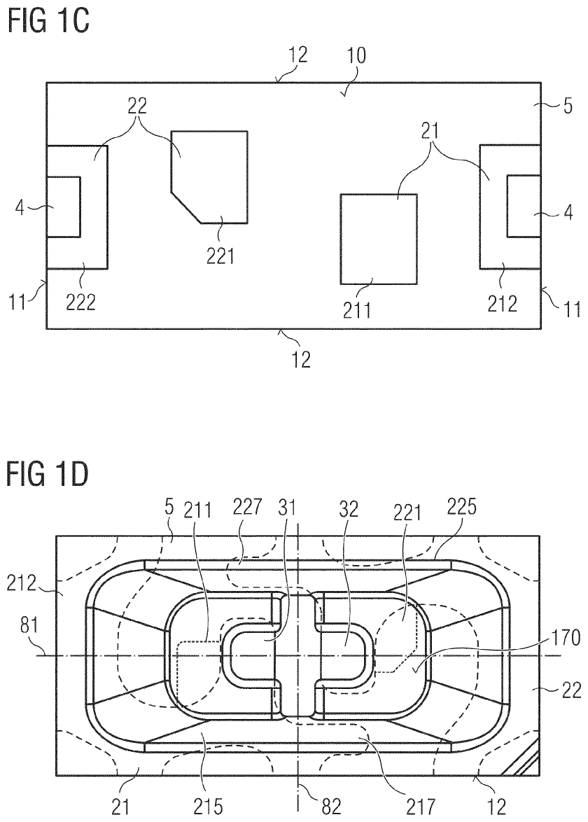

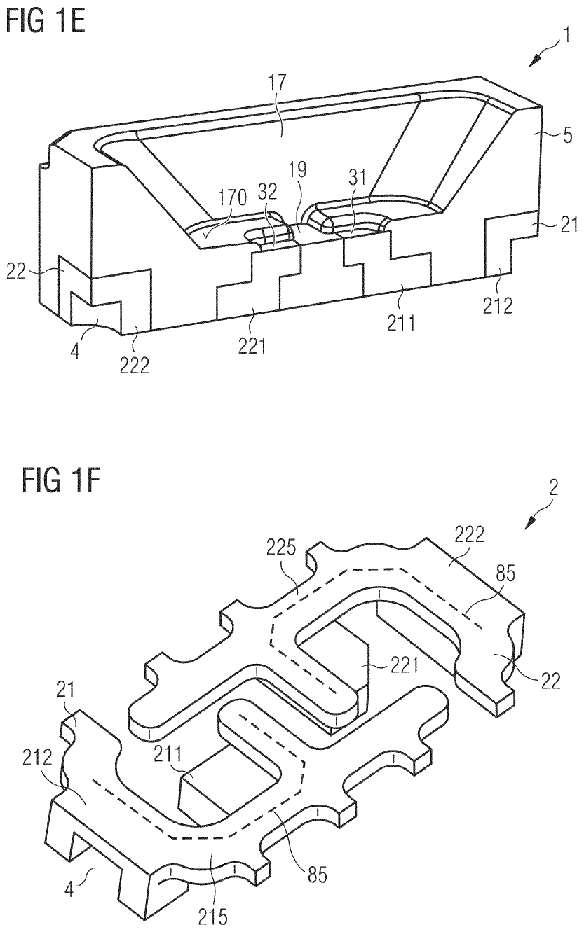

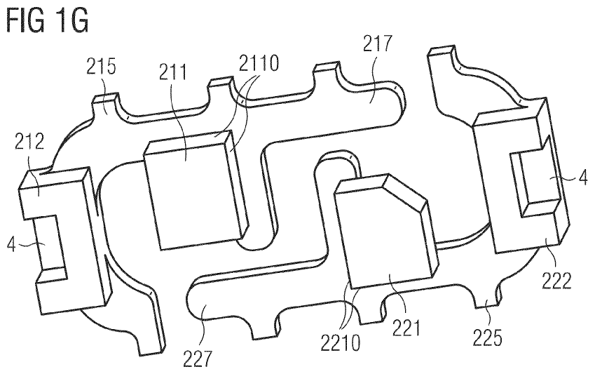

FIGS. 1A, 1B, 1C, 1D, 1E, 1F and 1G show an exemplary embodiment of a housing on the basis of a schematic plan view (FIG. 1A), a schematic sectional view along the longitudinal axis (FIG. 1B), a rear view (FIG. 1C), a schematic plan view showing the course of the lead frame (FIG. 1D), a perspective sectional view (FIG. 1E), as well as a schematic representation of the lead frame in a perspective front-side view (FIG. 1F) and a schematic rear-side view (FIG. 1G); and

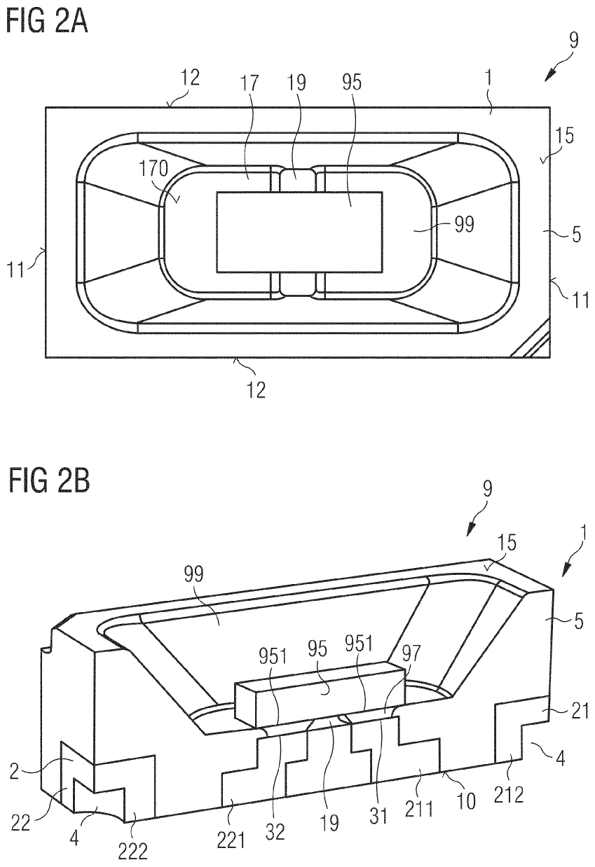

FIGS. 2A, 2B shows an exemplary embodiment of an optoelectronic semiconductor component in schematic plan view (FIG. 2A) and in an associated perspective sectional view (FIG. 2B).

Identical, similar or similarly acting elements are provided with the same reference signs in the figures. The figures are schematic representations and therefore not necessarily true to scale. In particular, comparatively small elements or layer thicknesses can be shown exaggeratedly large.

An exemplary embodiment of a housing 1 is illustrated in various views in FIGS. 1A to 1G.

The housing 1 extends in a vertical direction between a mounting side 10 and a front side 15 facing away from the mounting side.

The front side 15 comprises a cavity 17 for accommodating an optoelectronic semiconductor chip.

The housing 1 further comprises a lead frame 2 with a first lead frame part 21 and a second lead frame part 22. A housing body 5 is integrally moulded onto the lead frame 2 and connects the first lead frame part 21 and the second lead frame part 22 to each other in a mechanically stable manner. The housing body 5 has, for example, a polymer material and is produced by a moulding method. To increase the reflectivity of the housing body 5, reflective particles, for example titanium dioxide particles, can be added to the housing body 5.

In the cavity 17, the lead frame 2 is only exposed at a first connection point 31 of the first lead frame part 21 and at a second connection point 32 of the second lead frame part 22. A bottom face 170 has an indentation 19 in the region of the first connection point 31 and the second connection point 32, and these connection points are exposed in said recess. When an optoelectronic semiconductor chip is fastened in the housing 1 by means of a connecting means 97, the lateral extent of the connecting means can be delimited via the indentation 19.

Except in the region of the indentation 19, the housing body 5 thus completely covers the lead frame 2 in plan view of the housing 1. The first connection point 31 and the second connection point 32 are each small compared to the bottom face 170 of the cavity 17. For example, an area dimension of the first connection point 31 and an area dimension of the second connection point 32 are each at most 30% of an area dimension of the bottom face 170 of the cavity 17.

In the vertical direction, the lead frame 2 extends between a rear side 200 and a front side 205. The lead frame is etched from the rear side 200 and from the front side 205, so that the lead frame 2 has regions with different thicknesses.

Along a longitudinal axis 81, the housing 1 extends between two first side faces 11. Perpendicularly to the longitudinal axis, i.e. along the transverse axis 82, the housing extends between two second side faces 12 in plan view.

The longitudinal axis 81 and the transverse axis 82 are each formed centrally to the housing, so that the point of intersection of the longitudinal axis 81 and the transverse axis 82 forms a centre point 83 of the housing. The transverse axis runs between the first connection point 31 and the second connection point 32.

FIG. 1B shows a sectional view along the longitudinal axis 81 through the housing 1.

The first lead frame part 21 has a first inner region 211 and a first edge region 212. The first inner region 211 and the first edge region 212 each extend to the rear side 200 of the lead frame. As shown in FIG. 1C, the first inner region 211 and the first edge region 212 are exposed at the mounting side 10 and are thus accessible from the mounting side 10.

The second lead frame part 22 is analogous to the first lead frame part 21 and has a second inner region 221 and a second edge region 222.

The first edge region 212 and the second edge region 222 each have a recess 4 that extends to the first side face 11 and to the mounting side 10. During the mounting of the housing 1, the recess 4 can fulfil the function of a solder control structure.

The first lead frame part 21 and the second lead frame part 22 are each interrupted along the longitudinal axis 81, as can be seen from the sectional view in FIG. 1B. However, it is clear from FIG. 1D that the first lead frame part 21 and the second lead frame part 22 are each formed in one piece.

The first lead frame part 21 has a first front-side region 215, through which the first inner region 211 and the first edge region 212 are connected to each other. In FIG. 1D, the parts of the perimeter of the first lead frame part 21 and the second lead frame part 22 that are hidden by the housing body 5 are shown by dashed lines, wherein a perimeter of the first inner region 211 and of the second inner region 221 are illustrated by a dotted line.

The first front-side region 215 forms the first connection point 31. The second front-side region 225 forms the second connection point 32.

In FIGS. 1F and 1G, the lead frame parts of the lead frame 2 are shown without the housing body 5. In plan view of the housing 1, the first inner region 211 and the first edge region 212 are connected to each other via the first front-side region 215 along the longitudinal axis 81 of the housing 1, as seen only on one side of the longitudinal axis 81.

In the other half of the housing 1 along the longitudinal axis 81, the first lead frame part 21 is interrupted so that the first lead frame part 21 does not form a closed structure in plan view. The first lead frame part 21 and the second lead frame part 22, in particular their respective front-side regions, each have a C-shaped basic form, as illustrated by the line 85 in FIG. 1.

The first front-side region 215 is distanced from the rear side 200 of the lead frame 2, so that the first front-side region 215 has a comparatively small thickness, as does the second front-side region 225. Seen from the rear side of the housing 1, the first front-side region 215 and the second front-side region 225 are covered by material of the housing body 5. A mechanical force transmission due to thermomechanical stresses between the first edge region 212 and the first inner region 211 is reduced compared to the situation in which a connecting region between the first inner region and the first edge region is not thinned, in particular in conjunction with the interruption of the first lead frame part 21 and the second lead frame part 22 along the longitudinal axis 81.

This reduces the risk that thermomechanical stresses will cause an optoelectronic semiconductor chip fastened to the first connection point 31 and the second connection point 32 or an electrical connection between the optoelectronic semiconductor chip and the connection points 31, 32 to be damaged due to thermomechanical stresses.

The first lead frame part 21, in particular the first front-side region 215 further comprises a first extension 217. The first extension 217 extends across the transverse axis 82 to that side of the housing 1 in which the second inner region 221 of the second lead frame part and the second connection point 32 are arranged. The first extension 217 extends at least at points between the second connection point 32 and the second side face 12 of the housing 1.

Analogously, the second lead frame part 22, in particular the second front-side region 225, has a second extension 227, wherein the second extension extends beyond the transverse axis 82 onto that half of the housing 1 in which the first inner region 211 of the first lead frame part 21 is formed. Thus, in a side view of the housing 1, the first lead frame part 21 and the second lead frame part 22 overlap due to the extensions 217, 227.

Via the first extension 217 and the second extension 227, the mechanical stability of the housing 1 is improved, in particular with respect to a bending or a breaking stress.

For example, the first inner region 215 has a cuboid basic shape and is covered at points by the first front-side region 215. As shown in FIG. 1G, the first front-side region 215 extends along two edges 2110 of the first inner region, wherein these edges run perpendicular to each other.

Accordingly, the second front-side region 225 runs along two edges 2210 of the second inner region 221. This improves the mechanical stability of the housing, in particular when the lead frame is pressed into a film to produce the housing body 5 by a film assisted moulding method.

In respect of its basic shape, the lead frame 2 is point-symmetrical to the centre point 83, in particular apart from a marking for simplified identification of the polarity of the housing 1 in the form of a cut-off corner of the second inner region 212.

FIGS. 2A and 2B show an exemplary embodiment of an optoelectronic semiconductor component 9, in which the housing 1 is formed as described in conjunction with FIGS. 1A to 1G. The optoelectronic semiconductor component 9 further comprises an optoelectronic semiconductor chip 95. The first connection point 31 and the second connection point 32 are each electrically conductively connected to a contact 951 of the optoelectronic semiconductor chip 95, for example via a connecting means 97 such as a solder. The optoelectronic semiconductor chip 95 is formed in flip-chip geometry and has the contacts 951 in each case on the side facing the mounting side 10 of the housing 1. For example, the semiconductor chip 95 is a light-emitting diode having a sapphire substrate as a growth substrate and an active region based on nitride compound semiconductor material for generating radiation.

In plan view of the optoelectronic semiconductor component 9, the optoelectronic semiconductor chip 95 completely covers the first connection point 31 and the second connection point 32. In particular, the first connection point 31 and the second connection point 32 can be covered by metal material of the connection means 97. The indentation 19 of the housing 1 delimits the lateral extent of the connecting means 97.

Waste heat generated during operation of the optoelectronic semiconductor component 9 can be dissipated directly in the vertical direction via the first front-side region 215 and the first inner region 211, or via the second front-side region 225 and the second inner region 221 of the lead frame 2.

The optoelectronic semiconductor chip 95 is embedded in a potting compound 99. The potting compound 99 is expediently permeable to the radiation to be generated and/or received by the optoelectronic semiconductor chip and can, for example, be mixed with a luminescent material. In particular, the potting compound 99 does not adjoin the lead frame 2 of the optoelectronic semiconductor component 9 at any point, and therefore the material for the potting compound 99 can be selected independently of how well the material adheres to metal surfaces.

Furthermore, no bonding wires are required for the electrical contacting of the optoelectronic semiconductor chip 95. Thus, there is no risk of the potting compound 99 impairing the electrical contacting of the optoelectronic semiconductor chip 95, for example when soldering the optoelectronic semiconductor component 9 to a connection carrier such as a printed circuit board. Furthermore, there is no risk of corrosion of the lead frame 2 within the cavity 17, irrespective of whether the potting compound 99 is permeable to corrosive gases, such as hydrogen sulfide, and/or whether the potting compound 99 or the housing body 5 allows penetration paths to the lead frame 2 in the cavity 17.

The described embodiment of the housing 1 is particularly suitable for the realisation of small housing designs. For example, an extent of the housing along the longitudinal axis 81 is at most 3 mm or at most 2 mm. For example, the housing 1 is a housing for a light-emitting diode of the design 1608, i.e. a light-emitting diode with a footprint of 1.6×0.8 mm², in particular in QFN (Quad Flat No Lead) technology. The electrical connections of the housing 1 therefore do not protrude laterally beyond the housing body 5 in plan view.

The figures are true to scale for an exemplary embodiment of design 1608. However, the proportions of the individual elements can also deviate from this. Furthermore, the described construction of the housing is also suitable for other designs.

This patent application claims the priority of German patent application 10 2020 107 409.3, the content of the disclosure of which is hereby incorporated by reference.

The invention is not limited by the description with reference to the exemplary embodiments. Rather, the invention includes any new feature as well as any combination of features, which in particular includes any combination of features in the claims, even if this feature or combination is not itself explicitly indicated in the claims or the exemplary embodiments.

### List of reference signs

1 housing
10 mounting side
11 first side face
12 second side face
15 front side
17 cavity
170 bottom face
19 indentation
2 lead frame
200 rear side of the lead frame
205 front side of the lead frame
21 first lead frame part
211 first inner region
2110 edge of the first inner region
212 first edge region
215 first front-side region
217 first extension
22 second lead frame part
221 second inner region
2210 edge of the second inner region
222 second edge region
225 second front-side region
227 second extension
31 first connection point
32 second connection point
4 recess
5 housing body
81 longitudinal axis
82 transverse axis
83 centre point
85 line
9 semiconductor component
95 optoelectronic semiconductor chip
951 contact of the optoelectronic semiconductor chip
97 connecting means
99 potting compound

1. A housing for an optoelectronic semiconductor component with a mounting side, a lead frame, and a housing body which is integrally moulded onto the lead frame, wherein
the lead frame comprises a first lead frame part and a second lead frame part;
the housing body comprises a cavity on a front side facing away from the mounting side for accommodating an optoelectronic semiconductor chip;
the lead frame is exposed solely at a first connection point of the first lead frame part and at a second connection point of the second lead frame part of the lead frame in the
the first lead frame part has a first inner region and a first edge region;
the first inner region and the first edge region are exposed on the mounting side of the housing;
the first inner region in plan view of the housing overlaps with the first connection point
the first edge region is exposed on a first side face of the housing; and
the first inner region and the first edge region are connected to one another via a front-side region of the first lead frame part, wherein the front-side region is distanced from the mounting side.

2. The housing according to claim 1,
wherein a bottom face of the cavity in a region of the first connection point and the second connection point has an indentation, in which the first connection point and the second connection point are exposed.

3. (canceled)

4. The housing according to claim 1,
wherein the first edge region has a recess which is accessible on the mounting side and on a side face of the housing.

5. The housing according to claim 1, wherein the first front-side region in plan view of the housing runs along two edges of the first inner region.

6. The housing according to claim 1,
wherein the first lead frame part between the first inner region and the first edge region in plan view of the housing is interrupted along a longitudinal axis of the housing.

7. The housing according to claim 1,
wherein the first inner region and the first edge region in plan view of the housing, seen along a longitudinal axis of the housing, are connected to one another via the first front-side region only on one side of the longitudinal axis.

8. The housing according to claim 1,
wherein the front-side region of the first lead frame part has a first extension, which extends between the second connection point and a second side face of the housing, said second side face running parallel to a longitudinal axis of the housing.

9. The housing according to claim 8,
wherein the first extension, seen along the longitudinal axis, runs along at least 50% of an extent of the second connection point.

10. The housing according to one of the preceding claims claim 1,
wherein an area dimension of the first connection point and an area dimension of the second connection point is in each case at most 30% of an area dimension of a bottom face of the cavity.

11. The housing according to claim 1,
wherein the second lead frame part and the first lead frame part are point-symmetrical to one another in respect of their basic shape.

12. An optoelectronic semiconductor component with the housing according to claim 1 and with the optoelectronic semiconductor chip arranged in the cavity and electrically conductively connected to the first connection point and the second connection point.

13. The optoelectronic semiconductor component according to claim 12,
wherein the optoelectronic semiconductor chip covers the first connection point and the second connection point fully.

14. The optoelectronic semiconductor component according to claim 12,
wherein the first connection point and the second connection point in plan view of the optoelectronic semiconductor component are each at most half of a size of the optoelectronic semiconductor chip.

15. The optoelectronic semiconductor component according to claim 12, wherein the optoelectronic semiconductor chip is embedded in a potting compound, wherein the potting compound does not at any point directly border the lead frame.
